(19) United States
(12) Patent Application Publication
(10) Pub. No.: US 2018/0320883 A1
(43) Pub. Date: Nov. 8, 2018

(54) LIGHT MODULE HAVING A HEATSINK CRIMPED AROUND A PRINTED CIRCUIT BOARD, AND A METHOD FOR CRIMPING A HEAT SINK AROUND A PRINTED CIRCUIT BOARD

(71) Applicant: Flex Ltd., Singapore (SG)

(72) Inventors: Jordon Musser, Dallas, TX (US); Chris Stratas, Burlingame, CA (US)

(21) Appl. No.: 15/687,022

(22) Filed: Aug. 25, 2017

Related U.S. Application Data
(60) Provisional application No. 62/502,026, filed on May 5, 2017.

(51) Int. Cl. F21V 29/89; H05K 1/02; H05K 1/18; F21K 9/275; F21V 29/70; F21K 9/90

(52) U.S. Cl. CPC F21V 29/89; H05K 1/0204; H05K 1/181; F21K 9/275; F21K 9/272; F21K 9/90; H05K 2201/10106; H05K 2201/066; F21V 29/70

(57) ABSTRACT

A device is provided that includes a printed circuit board having a light emitting diode. The printed circuit board is substantially planar and has a length and a width. The printed circuit board includes two first edges extending substantially the length of the printed circuit board. The device also includes a heatsink extending substantially the width and the length of the printed circuit board. The heatsink includes edges along the length of the printed circuit board, and an edge of the printed circuit board is positioned in a channel on an edge of the heatsink. The channel is crimped. A method for manufacturing a light module according to the present disclosure includes positioning a first edge of a printed circuit board in a channel on a second edge of a heatsink. The method further includes crimping the channel.

### BACKGROUND

### 1. Technical Field

The present disclosure relates to lighting fixtures. More particularly, the present invention relates to a light module having a heatsink crimped around a printed circuit board to facilitate manufacturing and improve heat dissipation.

### 2. Discussion of Related Art

Lighting, also referred to as artificial lights, is important in commercial and residential environments. Indoor lighting is critical for use of interior spaces during day and night. Outdoor lighting enables the use of outdoor spaces safely during periods of darkness. Lights can be expensive to install and operate. Light-emitting diode (LED) lights can reduce the costs of installing and operating lights due to their long useful operating life and relatively low energy usage. LEDs are typically patterned on a printed circuit board (PCB).

LED lights generate significant heat, but operate better, and last longer, when heat is properly dissipated. Traditional heatsinks for LEDs often rely on attaching the PCB to a heatsink with adhesive tape, or by other time-consuming, expensive, and/or unmanageable methods. Therefore, there is a need for a light module having a PCB with a firmly affixed heatsink, which does not require significant time and/or expense to manufacture.

### SUMMARY

Provided in accordance with the present disclosure is a device that includes a printed circuit board having a light emitting diode. The printed circuit board is substantially planar and has a length and a width. The printed circuit board includes two first edges extending substantially the length of the printed circuit board. The device also includes a heatsink extending substantially the width and the length of the printed circuit board. The heatsink includes two second edges along the length of the printed circuit board. One of the first edges of the printed circuit board is positioned in a channel on a second edge of the heatsink, and the channel is crimped.

In an aspect of the present disclosure, the channel is two channels, and the two first edges of the printed circuit board are positioned in the two channels. In this aspect of the present disclosure, the two channels are crimped.

In another aspect of the present disclosure, the crimping mechanically couples the heatsink and the printed circuit board at the channel.

In additional aspects of the present disclosure, the crimping provides structural stability and heat conduction.

In another aspect of the present disclosure, the heatsink includes extruded aluminum. The crimping may include mechanically deforming the aluminum heatsink to couple to the printed circuit board.

In other aspects of the present disclosure, the device may include the printed circuit board interposed between the heatsink and a lens. The printed circuit board, the heatsink, and the lens may form in combination a first light module. The device may include a second light module, and two endcaps may be arranged on opposing ends of the first and second light modules. The two endcaps may mechanically couple to the first and second light modules and provide a seal to inhibit ingress from ends of the first and second light modules to the printed circuit board.

In still further aspects of the present disclosure, the heatsink includes a substantially planar base. The base may span substantially the width of the printed circuit board and may be substantially parallel to the printed circuit board.

A method for manufacturing a light module according to the present disclosure includes positioning a first edge of a printed circuit board in a channel on a second edge of a heatsink. The printed circuit board has a light emitting diode. The printed circuit board is substantially planar and has a length and a width. The two first edges of the printed circuit board extend substantially the length of the printed circuit board. The heatsink extends substantially the width and the length of the printed circuit board. The heatsink includes two second edges along the length of the printed circuit board. The method further includes crimping the channel.

In an aspect of the present disclosure, the positioning operation may be of the two first edges of the printed circuit board in two channels. The crimping operation may be of the two channels.

In an aspect of the present disclosure, the crimping operation may include mechanically coupling the heatsink and the printed circuit board at the channel.

In a further aspect of the present disclosure, the crimping operation may provide structural stability and heat conduction.

In another aspect of the present disclosure, the heatsink includes extruded aluminum. The crimping operation may include mechanically deforming the aluminum heatsink to couple to the printed circuit board.

In still further aspects of the present disclosure, the method may include positioning the printed circuit board between the heatsink and a lens. The printed circuit board, the heatsink, and the lens may form in combination a first light module. The method may further include arranging two endcaps on opposing ends of the first light module and a second light module. The two endcaps may be mechanically coupled to the first and second light modules and may provide a second seal to inhibit ingress from ends of the first and second light modules to the printed circuit board.

Further, to the extent consistent, any of the aspects described herein may be used in conjunction with any or all of the other aspects described herein.

### BRIEF DESCRIPTION OF THE DRAWINGS

Various aspects and features of the present disclosure are described herein below with references to the drawings.

FIG. 1 is a perspective view of an exemplary embodiment of a light fixture according to the present technology.

FIG. 2 is an exploded view of an exemplary embodiment of a light fixture according to the present technology.

FIG. 3 is a diagram illustrating an exploded view of a light module according to an exemplary embodiment of the present technology.

FIG. 4 is a diagram illustrating a cross-sectional view of a printed circuit board having an LED, and mounted on a heatsink shown in a partial view, prior to crimping the heatsink around the printed circuit board, according to an exemplary embodiment of the present technology.

FIGS. 5A-5B are diagrams illustrating cross-sectional, partial views of light modules before a heatsink is crimped around a printed circuit board and after the heatsink is crimped around the printed circuit board, according to an exemplary embodiment of the present technology.

FIGS. 6A-6B are diagrams illustrating cross-sectional views of the pre-crimp and the crimp shown in FIGS. 5A-5B according to an exemplary embodiment of the present technology.

FIG. 7 is a flow chart illustrating an exemplary method according to an exemplary embodiment of the present technology.

### DETAILED DESCRIPTION

The present disclosure is directed, in part, to devices and methods for providing artificial light. In particular, the present technology addresses problems associated with the significant heat generated by LED lights. A light module is described having a heatsink crimped around a PCB to improve heat dissipation and reduce manufacturing time and/or costs, and a method for making a light module having a heatsink crimped around a PCB.

The present disclosure provides a light module having a firmly affixed heatsink, which does not require significant time and/or expense to manufacture. Crimping a heatsink around an LED PCB may include mechanically deforming an aluminum heatsink to capture and press the PCB directly to the extruded aluminum heatsink. In this manner, the use of thermally conductive adhesive tape to attach the PCB to a heatsink may be eliminated.

Light modules (also referred to as light fixtures, fixtures, or modules) are provided. Light modules may also include a light-emitting diode (LED) pattern on a printed circuit board (PCB), and/or an aluminum heatsink. Light modules according to the present technology may include a heatsink designed for LED modules that includes a custom, optimized aluminum extruded heatsink to efficiently cool LEDs using natural convection.

Light fixtures according to the present technology may include any number of LEDs patterned on a PCB, arranged in series and/or parallel strings.

Light modules according to the present technology may also include a custom extruded plastic lenses with engineered optics to provide maximum light transmission and provide various types of light distribution (for example, wide and aisle distributions).

Modular wire guards may be provided that include steel wire guards for protecting the lenses. The module wire guards may be designed to protect only one module each, and in this manner, the modular design may be used to fit any number of modules. In this manner, the same wire guard may be used in light fixtures having two, four, six, or any number of light modules per fixture.

Embodiments of the present disclosure are now described in detail with reference to the drawings in which like reference numerals designate identical or corresponding elements in each of the several views. Additionally, in the drawings and in the description that follows, terms such as front, rear, upper, lower, top, bottom, and similar directional terms are used simply for convenience of description and are not intended to limit the disclosure. In the following description, well-known functions or constructions are not described in detail to avoid obscuring the present disclosure in unnecessary detail.

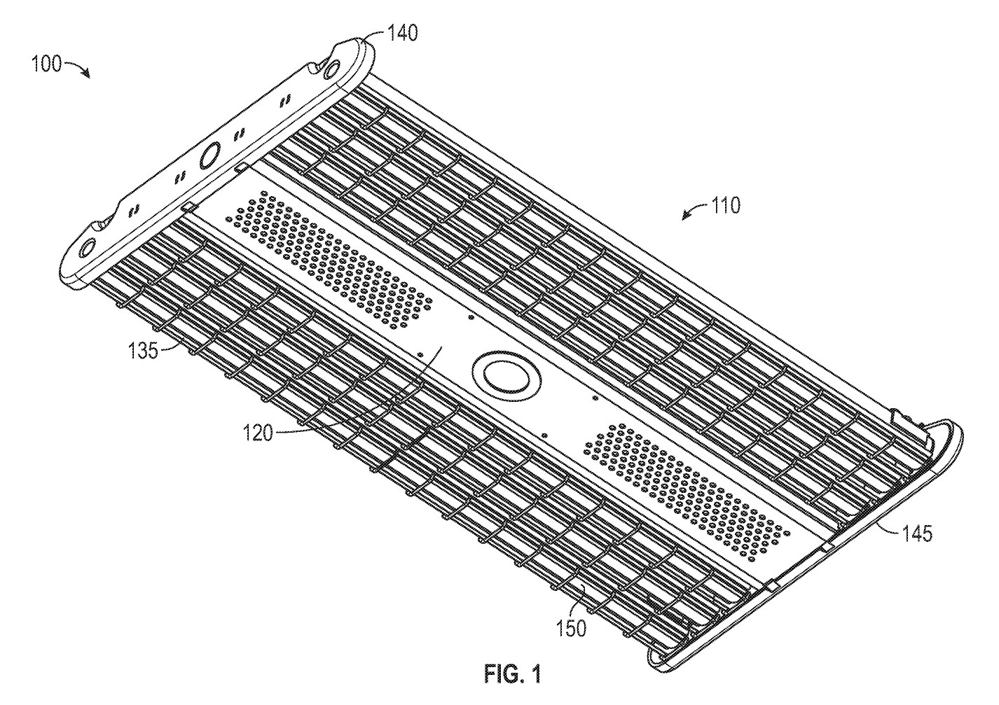

With reference to FIG. 1, light fixture 100 is shown in a perspective view. Light fixture 100 includes light modules 110. As shown in FIG. 1, light fixture 100 includes six light modules, each being linear and with three light modules arranged on one side of wireway 120, and three light modules arranged on the other side of wireway 120. Alternatively, light fixture 100 may include two or four light modules, or more, which may be arranged in equal numbers on either side of wireway 120. In still further exemplary embodiments, the number of light modules may not be evenly divided on either side of wireway 120, and light fixture 100 may include an odd number of light modules. Arranged on opposing ends of light modules 110 and wireway 120 are first endcap 140 and second endcap 145. Light modules in light fixture 100 include, or are provided with, wire guards to protect lights and or lenses of the light modules from impacts without excessively impairing the illumination provided by the light modules. As shown in FIG. 1, wire guard 150 is a modular wire guard arranged on outer light module 135.

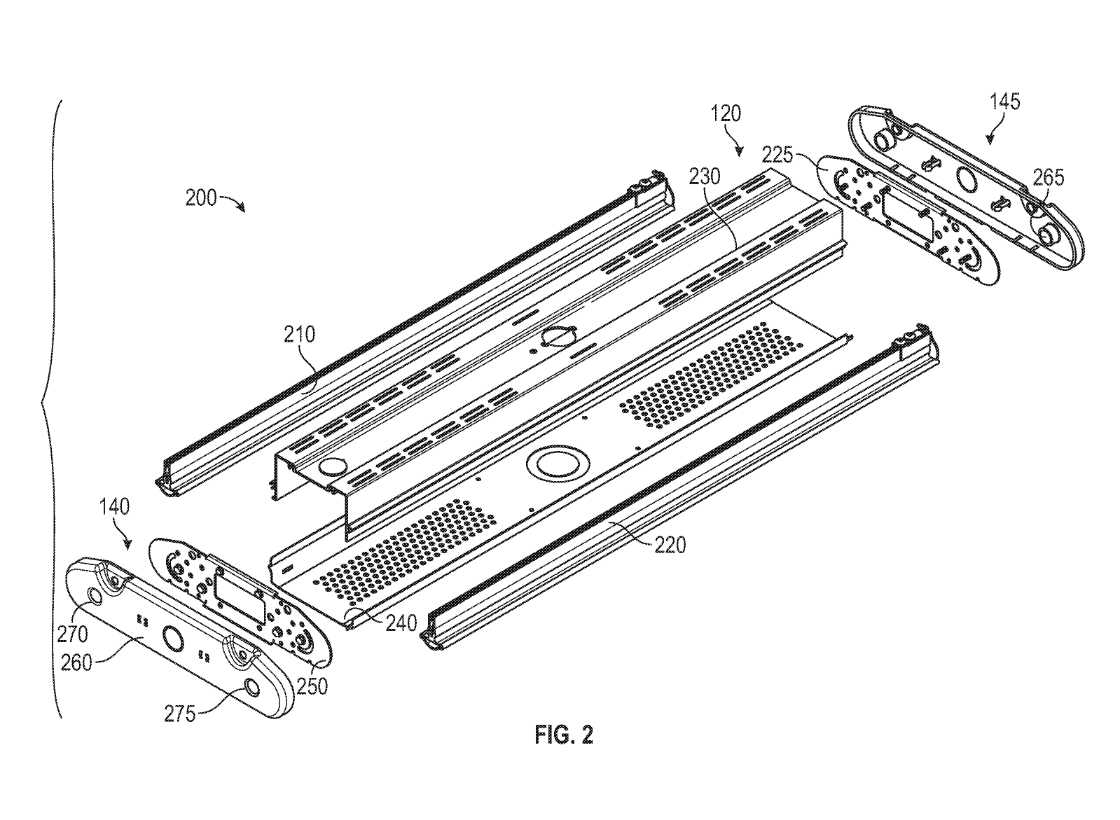

FIG. 2 is an exploded view of light fixture 200 according to the present technology. Light fixture 200 includes two light modules, namely first outer light module 210 and second outer light module 220. Wireway 120 is shown in FIG. 2 disassembled into upper wireway section 230 and lower wireway section 240. Upper wireway section 230 and lower wireway section 240 may combine to form wireway 120, including an interior space to accommodate wires and/or drivers for powering LED lights in first light module 210 and second outer light module 220. Wireway 120 may also function as a heatsink for the LED drivers. Wireway 120 may permit direct access to electrical components housed therein upon removal of lower wireway section 240 and/or upper wireway section 230.

First endcap 140 is shown in FIG. 2 disassembled into first inner endcap 250 and first outer endcap 260. Second endcap 145 is also shown in FIG. 2 disassembled into second inner endcap 255 and second outer endcap 265. First inner endcap 250 and second inner endcap 255 may attach to, or alternatively, function as mounting plates for, opposite ends of first outer light module 210, second outer light module 220, and wireway 120. In this manner, the relative distances and directions between first outer light module 210, second outer light module 220, and wireway 120 with respect to each other may be fixed.

First outer endcap 260 and second outer endcap 265 may be composed of plastic or any other appropriate material, and may provide an aesthetic appearance and/or operate to protect the wiring of the module assemblies.

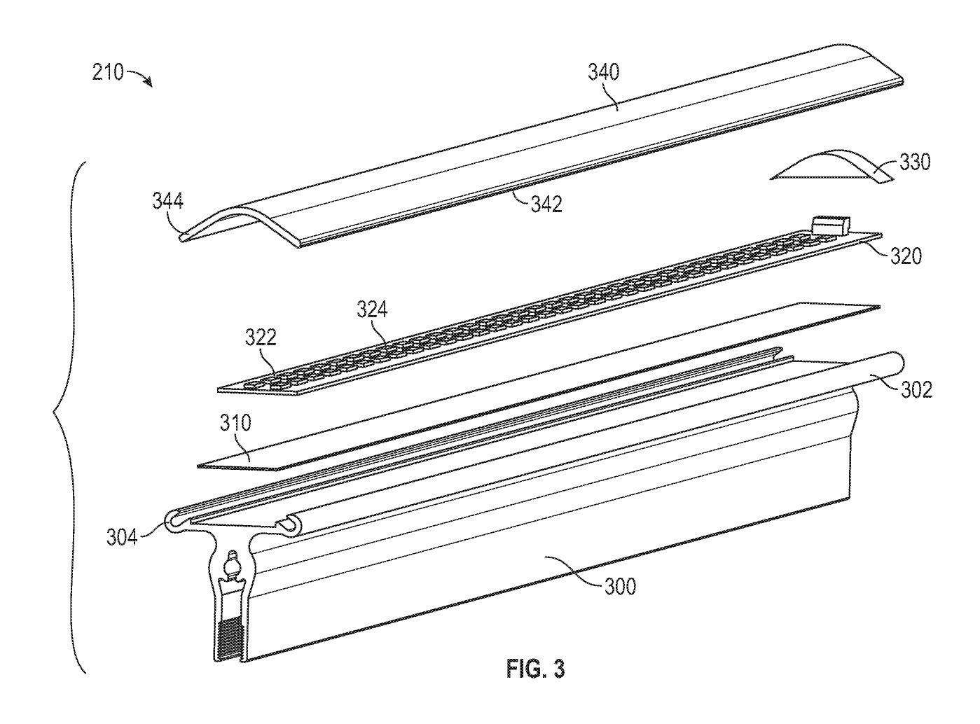

FIG. 3 is a diagram illustrating an exploded view of light module 210 according to an exemplary embodiment of the present technology. Shown in FIG. 3 is heatsink 300, which may be formed by extruding aluminum, and thermal tape 310, which may be thermally conductive adhesive tape used to attach PCB assembly 320 to heatsink 300. Heatsink 300 includes two edges 302, 304. In alternative exemplary embodiments, thermal tape 310 may not be used, and PCB assembly 320 may be attached to heatsink 300 by any appropriate method. For example, in exemplary embodiments of the present disclosure, heatsink 300 is attached to PCB assembly 320 by crimping a channel formed from heatsink 300 that receives an edge of PCB assembly 320. PCB assembly 320 may include LEDs and connectors on a printed circuit board, and may have short edge 322 defining a width, and long edge 324 defining a length. At an end of PCB assembly 320 may be positioned connector cover 330, which may be a flame retardant cover for a connector on PCB assembly 320. Covering the length of PCB assembly 320 may be lens 340, which may be an extruded plastic lens, or a lens made of any other appropriate material. Lens 340 includes two edges 342, 344, defining an arc between them.

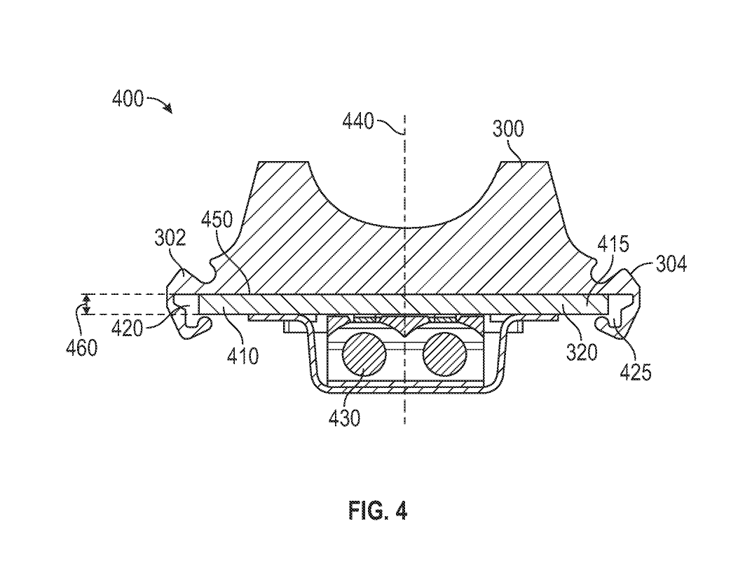

FIG. 4 is a diagram illustrating a cross-sectional, partial view of pre-crimped PCB-heatsink assembly 400. Pre-crimped PCB-heatsink assembly 400 includes PCB assembly 320 and heatsink 300. Heatsink 300 is shown in a partial view in FIG. 4, prior to crimping heatsink 300 around PCB assembly 320. PCB assembly 320 may include two first edges 410, 415 arranged on a long edge of PCB assembly 320, which may each have thickness 420. Heatsink 300 includes two edges 302, 304, which each may include uncrimped channel 420, 425. Uncrimped channel 420, 425 may each be of a width slightly larger than thickness 460. Two first edges 410, 415 of PCB assembly 320 may be positioned in uncrimped channels 420, 425 of heatsink 300. In this manner, heatsink 300 may be ready to be crimped during assembly to couple PCB assembly 320 to heatsink 300. PCB assembly 320 includes LED 430 mounted substantially on center line 440, which may bisect the cross-section of pre-crimped PCB-heatsink assembly 400. Contact interface 450 formed between heatsink 300 and PCB assembly 320 when uncrimped channel 420, 425 are later crimped may function to conduct heat from LED 430 to heatsink 300. A heat conductive paste may be employed to ensure good contact at the contact interface 450 between the PCT assembly 320 and the heatsink 300.

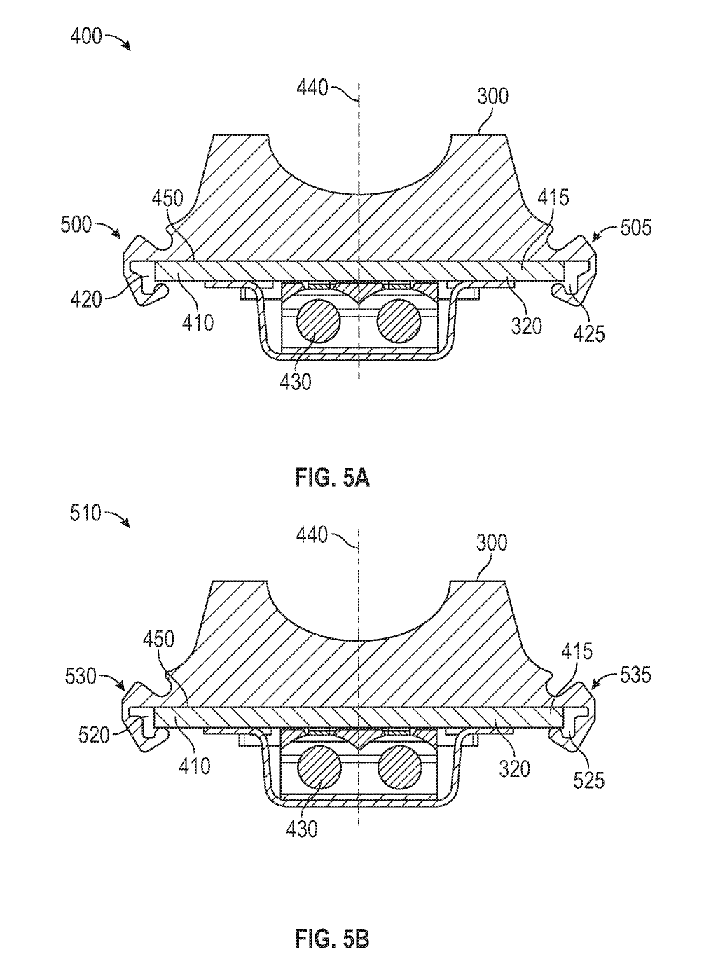

FIG. 5A shows the diagram illustrating a cross-sectional, partial view of pre-crimped PCB-heatsink assembly 400 shown in FIG. 4. Pre-crimped PCB-heatsink assembly 400 includes PCB assembly 320 and a partial view of heatsink 300, prior to crimping heatsink 300 around PCB assembly 320. PCB assembly 320 includes two first edges 410, 415. Heatsink 300 includes uncrimped channels 420, 425. Two first edges 410, 415 of PCB assembly 320 may be positioned in uncrimped channels 420, 425 of heatsink 300 to form pre-crimp couplings 500, 505. PCB assembly 320 includes LED 430 mounted substantially on center line 440, which may bisect the cross-section of pre-crimped PCB-heatsink assembly 400.

FIG. 5B shows the diagram illustrating a cross-sectional, partial view of crimped PCB-heatsink assembly 510. Heatsink 300 may be crimped during assembly to couple PCB assembly 320 to heatsink 300 to form crimped PCB-heatsink assembly 510. Crimped PCB-heatsink assembly 510 includes PCB assembly 320 and a partial view of heatsink 300, after crimping heatsink 300 around PCB assembly 320. PCB assembly 320 includes two first edges 410, 415. Heatsink 300 includes crimped channels 520, 525. Two first edges 410, 415 of PCB assembly 320 may be positioned in crimped channels 520, 525 of heatsink 300 to form crimp couplings 530, 535. PCB assembly 320 includes LED 430 mounted substantially on center line 440, which may bisect the cross-section of crimped PCB-heatsink assembly 510.

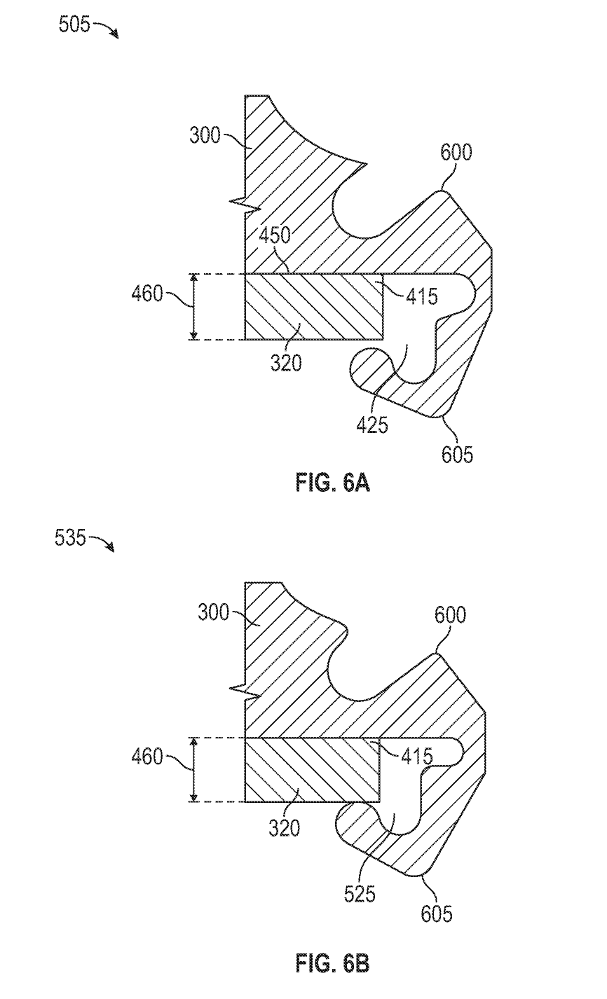

FIG. 6A is a diagram illustrating pre-crimp coupling 505, including a cross-sectional view of uncrimped channel 425 of heatsink 300 shown in FIG. 5A. FIG. 6A shows first edge 415 of PCB assembly 320 received in uncrimped channel 425 of heatsink 500. Uncrimped channel 425 is arranged on edge 304 of heatsink 300, and includes pressing surfaces 600, 605, for pressing against when later crimping uncrimped channel 425. Alternatively, other surfaces of heatsink 300 may be pressed to mechanically deform uncrimped channel 425. As shown in FIG. 6A, an airgap exists around first edge 415 in uncrimped channel 425. Therefore, pre-crimp coupling 505 may not couple PCB assembly 320 to heatsink 300, and may not yet provide effective heat conductivity between PCB assembly 320 and heatsink 300 via contact interface 450.

FIG. 6B is a diagram illustrating crimp coupling 535, including a cross-sectional view of crimped channel 525 of heatsink 300 shown in FIG. 5B. FIG. 6B shows first edge 415 of PCB assembly 320 received in crimped channel 525 of heatsink 500. Crimped channel 525 is arranged on edge 304 of heatsink 300, and includes pressing surfaces 600, 605, for pressing against when crimping crimped channel 525. As shown in FIG. 6B, no airgap exists around first edge 415 in crimped channel 525, and crimp coupling 535 may couple PCB assembly 320 to heatsink 300. Therefore, crimp coupling 535 may provide effective heat conductivity between PCB assembly 320 and heatsink 300 via contact interface 450. During manufacturing of the light module, pre-crimp coupling 525 may be mechanically deformed to form crimp coupling 535 by pressing on pressing surfaces 600, 605.

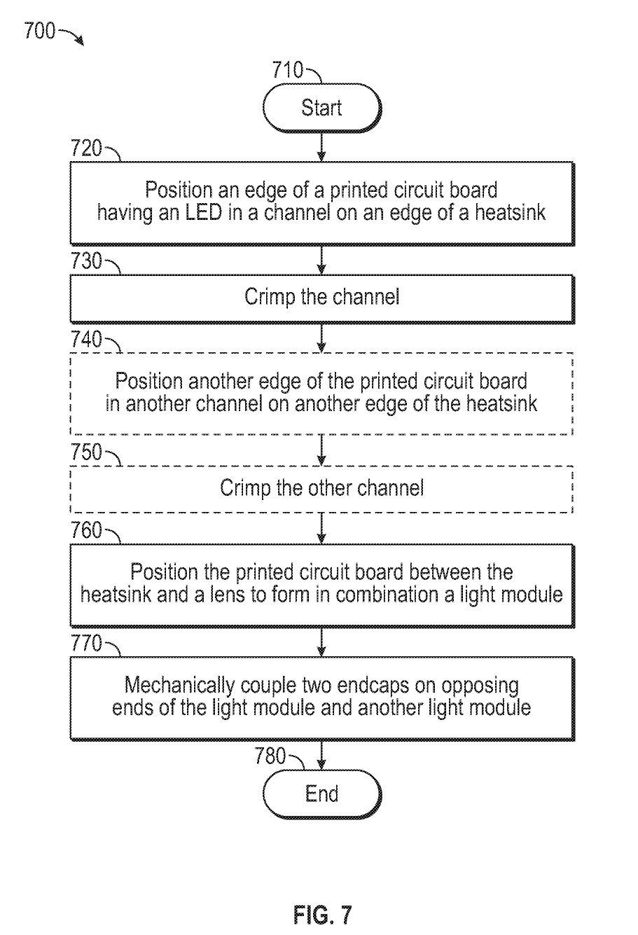

FIG. 7 is a flow chart illustrating exemplary method 700 according to an exemplary embodiment of the present technology, in which optional steps are shown with broken lines. Method 700 begins at start circle 710 and proceeds to operation 720, which indicates to position an edge of a printed circuit board having an LED in a channel on an edge of a heatsink. From operation 720, the flow in method 700 proceeds to operation 730, which indicates to crimp the channel. From operation 730, the flow in method 700 proceeds to optional operation 740, which indicates to position another edge of the printed circuit board in another channel on another edge of the heatsink. From optional operation 740, the flow in method 700 proceeds to optional operation 750, which indicates to crimp the other channel. From optional operation 750, the flow in method 700 proceeds to optional operation 760, which indicates to position the printed circuit board between the heatsink and a lens to form in combination a light module. From optional operation 760, the flow in method 700 proceeds to optional operation 770, which indicates to mechanically couple two endcaps on opposing ends of the light module and another light module. From optional operation 770, the flow in method 700 proceeds to end circle 780. The order of operations shown in FIG. 7 is exemplary only, and operations may be performed in a different order. For instance, operation 730 may be performed after optional operation 740, or simultaneous with optional operation 750 in some exemplary embodiments.

Detailed embodiments of such devices, systems incorporating such devices, and methods using the same are described above. However, these detailed embodiments are merely examples of the disclosure, which may be embodied in various forms. Therefore, specific structural and functional details disclosed herein are not to be interpreted as limiting but merely as a basis for the claims and as a representative basis for allowing one skilled in the art to variously employ the present disclosure in virtually any appropriately detailed structure. The scope of the technology should therefore be determined with reference to the appended claims along with their full scope of equivalents.

1. A device comprising:
a printed circuit board having at least one light emitting diode, the printed circuit board being substantially planar and having a length and a width, the printed circuit board including two first edges extending substantially the length of the printed circuit board; and
a heatsink extending substantially the width and the length of the printed circuit board, the heatsink including two second edges along the length of the printed circuit board, at least one of the first edges of the printed circuit board being positioned in at least one channel on at defined by at least one of the second edges of the heatsink, the at least one channel being crimped, wherein the at least one of the second edges of the heatsink has an arm extending over the at least one of the first edges of the printed circuit board, the arm including:
a first portion extending from a substantially planar base of the heatsink; and
a second portion extending from the first portion at an angle toward the printed circuit board and the base of the heat sink.

2. The device of claim 1, wherein:
the at least one channel is two channels;
the two first edges of the printed circuit board are positioned in the two channels; and
the two channels are crimped.

3. The device of claim 1, wherein the crimping mechanically couples the heatsink and the printed circuit board.

4. The device of claim 3, wherein the crimping provides structural stability and heat conduction.

5. The device of claim 1, wherein the heatsink comprises extruded aluminum.

6. The device of claim 5, wherein the crimping comprises mechanically deforming the aluminum heatsink to couple to the printed circuit board.

7. The device of claim 1, wherein the printed circuit board is interposed between the heatsink and a lens, and wherein the printed circuit board, the heatsink, and the lens form, in combination a first light module; the device further comprising:
at least one second light module; and
two endcaps arranged on opposing ends of the first and second light modules, the two endcaps being mechanically coupled to the first and second light modules and providing a seal to inhibit ingress from the ends of the first and second light modules to the printed circuit board.

8. The device of claim 1, wherein the base spans substantially the width of the printed circuit board and is substantially parallel to the printed circuit board.

9. A method for manufacturing a light module, comprising:
positioning at least one of two first edges of a printed circuit board in at least one channel defined in at least one of two second edges of a heatsink, the at least one of the second edges of the heatsink having an arm extending over the at least one of the first edges of the printed circuit board, the printed circuit board having at least one light emitting diode, the printed circuit board being substantially planar and having a length and a width, the two first edges of the printed circuit board extending substantially the length of the printed circuit board, the heatsink extending substantially the width and the length of the printed circuit board, the heatsink including the two second edges along the length of the printed circuit board; and
crimping the arm of the at least one of the second edges of the heatsink to capture the at least one of the first edges of the printed circuit board in the at least one channel, wherein the arm extends over the at least one of the first edges of the printed circuit board prior to and after crimping.

10. The method of claim 9, wherein:
the at least one channel is two channels;
the positioning operation includes positioning the two first edges of the printed circuit board in the two channels; and
the crimping operation includes crimping the two first edges of the printed circuit board to capture the two first edges of the printed circuit board in the two channels.

11. The method of claim 9, wherein the crimping operation comprises mechanically coupling the heatsink and the printed circuit board.

12. The method of claim 9, wherein the crimping operation provides structural stability and heat conduction.

13. The method of claim 9, wherein:
the heatsink comprises extruded aluminum; and
the crimping operation comprises mechanically deforming the aluminum heatsink to couple to the printed circuit board.

14. The method of claim 9, further comprising:
positioning the printed circuit board between the heatsink and a lens, the printed circuit board, the heatsink, and the lens forming in combination a first light module; and
arranging two endcaps on opposing ends of the first light module and at least one second light module, the two endcaps being mechanically coupled to the first and second light modules and providing a second seal to inhibit ingress from the ends of the first and second light modules to the printed circuit board.

15. The method according to claim 9, wherein prior to the crimping operation, the arm of the at least one of the second edges of the heatsink includes:
a first portion extending from a substantially planar base of the heatsink at an angle toward a central longitudinal axis defined by the heatsink; and
a second portion extending from the first portion at an angle downwardly toward the printed circuit board and the base of the heat sink.

16. The method according to claim 15, wherein the crimping operation closes a gap between an end of the second portion of the arm and the printed circuit board.

17. The device of claim 1, wherein the first portion of the arm extends toward a central longitudinal axis defined by the heatsink, and the second portion of the arm extends from the first portion at the angle downwardly toward the printed circuit board and the base of the heat sink.
